(19) United States
(12) Patent Application Publication
(10) Pub. No.: US 2026/0247886 A1
(43) Pub. Date: Aug. 20, 2026

(54) PLASMA PROCESSING METHOD

(71) Applicant: Hitachi High-Tech Corporation, Minato-ku, Tokyo (JP)

(72) Inventors: Ryo YOKOYAMA, Tokyo (JP); Taku IWASE, Hsinchu (TW); Shuji ENOKIDA, Tokyo (JP)

(21) Appl. No.: 18/840,189

(22) PCT Filed: Aug. 28, 2023
(86) PCT No.: PCT/JP2023/031064

§ 371 Date: Aug. 21, 2024

(51) Int. Cl. H10P 50/28; H10D 84/01

(52) U.S. Cl. CPC H10P 50/283; H10D 84/0151

(57) ABSTRACT

As an etching method of an object to be processed, which is capable of protecting pores in a porous film and a joint referred to as a seam present in the porous film without requiring replacement of a plurality of gases, a plasma processing method for plasma etching a Low-k film having a void is provided in which plasma generated by a mixed gas of a fluorine element containing gas and a carbon element containing gas is used to etch the Low-k film containing a silicon element.

### TECHNICAL FIELD

The present invention relates to an etching method of an object to be processed such as a semiconductor device, and more particularly to an etching method suitable for etching a semiconductor device having a porous film.

### BACKGROUND ART

In the field of semiconductors, a low dielectric constant interlayer insulating film material (hereinafter referred to as a “Low-k film”) is being developed for a next generation semiconductor. The Low-k film is a generic term for a film having a relative dielectric constant lower than 4.0. The Low-k film is, for example, a SiOC film.

In order to reduce the relative dielectric constant of the Low-k film as much as possible, it is necessary to form a porous film containing a large number of pores. However, when the pores are introduced, mechanical strength such as modulus of elasticity and hardness is significantly reduced in proportion to an amount of the pores, and thus the film is easily damaged by plasma etching, and problems such as peeling easily occur during a process.

In manufacture of such an electronic device, a fine pattern formed on a photoresist by lithography is transferred to a hard mask such as a TiN film, a SiO₂ film, or a Si₃N₄ film by the plasma etching as required, and a subsequent process of transferring the pattern to the porous film is performed.

In the plasma etching, radicals are generated by exciting an etching gas in a processing container of a plasma processing apparatus, but the radicals can enter the pores of the porous film and damage the porous film. Therefore, a technique for protecting the porous film from the radicals is proposed.

For example, PTL 1 proposes that a fluorocarbon gas and a hydrocarbon gas are introduced into a processing chamber under a specific condition, the gases are liquefied in pores of a porous film by capillary condensation, the fluorocarbon gas and the hydrocarbon gas are then replaced with an etching gas, such as a SiF₄ gas or an NF₃ gas, and then plasma is generated from the etching gas to perform etching processing.

In this method, the pores are protected by the liquefied fluorocarbon gas, the hydrocarbon gas, or the like, and thus it is expected that the etching processing can be performed without damaging the pores.

### CITATION LIST

### Patent Literature

PTL 1: JP2016-207768A

### SUMMARY OF INVENTION

### Technical Problem

In the technique described in PTL 1, there have been problems that a two-step process of a process of introducing the gases to be liquefied in the pore and filling the pore with a liquefied component and a process of replacing the gases with the etching gas and then performing the etching with the etching gas is necessary, and it takes time for the process. In addition, in order to liquefy the gas in the pores, it is necessary to more strictly control a pressure, a temperature, and the like in the processing chamber.

An object of the invention is to provide an etching method of an object to be processed, which is capable of protecting pores in a porous film and a joint referred to as a seam present in the porous film during etching processing without requiring replacement of a plurality of gas species.

### Solution to Problem

A configuration of the invention for achieving the above object is as follows.

A plasma processing method for plasma etching a Low-k film having a void is a plasma processing method in which plasma generated from a mixed gas of a fluorine element containing gas and a carbon element containing gas is used to etch the Low-k film containing a silicon element.

### Advantageous Effects of Invention

According to the invention, it is possible to provide an etching method of an object to be processed, which is capable of protecting pores in a porous film and a joint referred to as a seam present in the porous film during etching processing without requiring replacement of a plurality of gas species.

### BRIEF DESCRIPTION OF DRAWINGS

FIG. 1 is a schematic configuration diagram showing a plasma processing apparatus according to an embodiment of the invention.

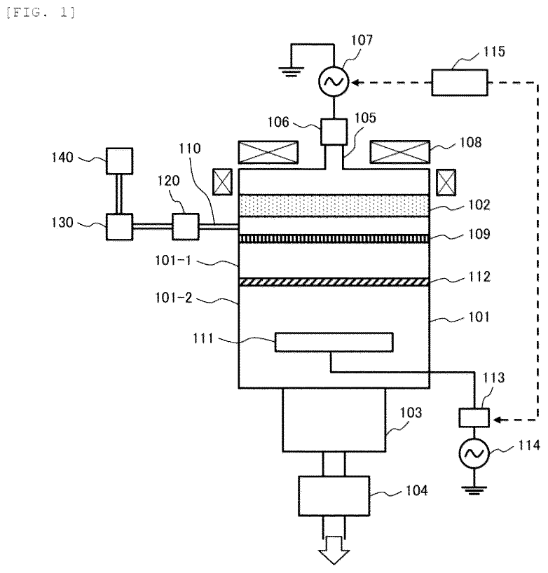

FIG. 2 is a flowchart of an etching method according to the invention.

FIG. 3 is a timing chart of the etching method according to the invention.

FIG. 4 shows film structures of a wafer used in the invention and etching shapes when the wafer is etched by a technique according to the invention.

### DESCRIPTION OF EMBODIMENTS

First, an example of a plasma etching apparatus for implementing a plasma processing method according to the invention will be described.

1 shows a configuration of the plasma etching apparatus. In this case, a vacuum container 101 constituting a processing chamber is a cylindrical container made of a conductive material such as aluminum, and is electrically grounded (earth). An upper opening of the vacuum container 101 is sealed by a top plate 102 made of a material allowing an electromagnetic wave to be transmitted, for example, quartz. A device for depressurizing and evacuating an inside of the vacuum container 101 to a predetermined pressure, such as, a turbo molecular pump 103 and an auxiliary pump connected thereto, such as, a dry pump 104 are connected to a lower center of the vacuum container 101. A waveguide 105 covering the top plate 102 is provided on an upper portion of the top plate 102, and a radio frequency power supply for plasma generation (hereinafter referred to as a “plasma power supply 107”) is connected via a matching device 106.

In this case, the plasma power supply 107 oscillates a microwave of 2.45 GHZ. The oscillated microwave propagates through the waveguide 105 and is introduced into the vacuum container 101 via the top plate 102. A solenoid coil 108 for forming a magnetic field in the vacuum container 101 is wound around an outside of the vacuum container 101. A shower plate 109 is provided at an upper portion of the vacuum container 101 below the top plate 102, and a gas supply pipe 110 is connected between the top plate 102 of the vacuum container 101 and the shower plate 109. A valve group 120, a flow rate controller group 130, and a gas source group 140 are connected to the gas supply pipe 110. The gas source group 140 includes a plurality of gas sources. The plurality of gas sources include one or more gas sources that supply a fluorine-based gas and a carbon-based gas to be described later. The valve group 120 and the flow rate controller group 130 can simultaneously supply the fluorine-based gas and the carbon-based gas to the gas supply pipe 110 at a predetermined flow rate.

A processing gas is supplied from the gas supply pipe 110 to a space between the top plate 102 and the shower plate 109, and the processing gas is supplied into the processing chamber formed in the vacuum container 101 via the shower plate 109. A sample stage 111 is provided in the vacuum container 101, a wafer is loaded from a wafer loading port (not shown), and is disposed and held on the sample stage 111. A biasing radio frequency power supply 114 is connected to the sample stage 111 via a bias matching device 113. The bias matching device is controlled by a control device 115, and a radio frequency bias applied to the sample stage 111 is controlled.

In the apparatus having the configuration as described above, the processing gas supplied into the vacuum container 101 is converted into plasma by an action (for example, electron cyclotron resonance (ECR)) of a microwave electric field introduced via the top plate 102 and the magnetic field formed by the solenoid coil 108, and the plasma is formed in a space between the shower plate 109 and the sample stage 111. In addition, an intensity of the magnetic field in which the plasma is formed is near a plane of 875 Gauss, and is referred to as an ECR plane.

Further, in the present apparatus, an ion shielding plate 112 made of the material allowing the electromagnetic wave to be transmitted, for example, quartz, divides the vacuum container 101 into a vacuum container upper region 101-1 and a vacuum container lower region 101-2. If the plasma can be generated in the vacuum container upper region 101-1, which is above the ion shielding plate 112, ions can be shielded and a sample can be processed using only radicals. As described above, a position at which the plasma is formed can be controlled by the solenoid coil 108. Since the ion shielding plate 112 is made of the material allowing the electromagnetic wave to be transmitted, it is also possible to perform dry etching with normal plasma by controlling the solenoid coil 108 such that the ECR plane is formed in the vacuum container lower region 101-2.

When the plasma is generated in the vacuum container lower region 101-2 to perform the dry etching, radio frequency power is applied from the biasing radio frequency power supply 114 to the sample stage 111 via the bias matching device 113. The radio frequency power applied to the sample stage 111 is controlled independently of the plasma generation, and a bias voltage for causing ions in the plasma to enter the wafer is generated. An output of each of the plasma power supply 107 and the biasing radio frequency power supply 114 is controlled by the control device 115.

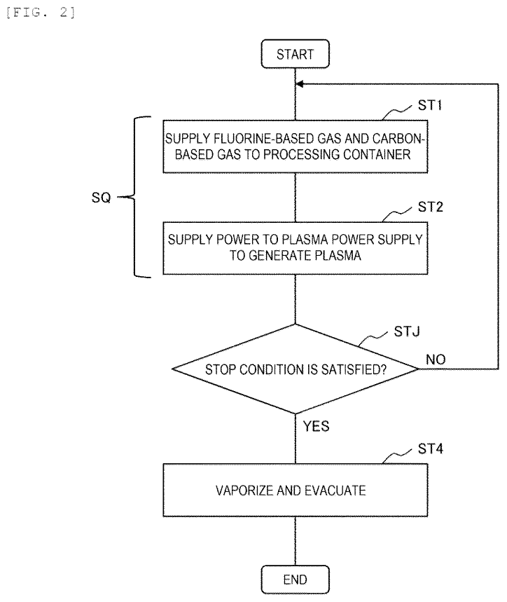

Next, processing conditions in the etching method according to the present embodiment will be described. A flowchart of the etching method according to the invention is shown in FIG. 2. The fluorine-based gas and the carbon-based gas are simultaneously introduced into the processing container (step ST1). During the introduction, the radio frequency power is simultaneously supplied to the plasma power supply to convert the introduced gases into the plasma, and the etching is started (step ST2). In the flowchart in FIG. 2, ST1 and ST2 are described one above the other, but ST1 and ST2 are actually performed substantially simultaneously (step SQ). It is determined whether the etching is completed and a stop condition is satisfied (step STJ). When the stop condition is satisfied (YES), the inside of the vacuum container 101 is evacuated (step ST4), and the process ends. It should be noted that the determination in step STJ as to whether the stop condition is satisfied is made by end point detection which is a well-known technique.

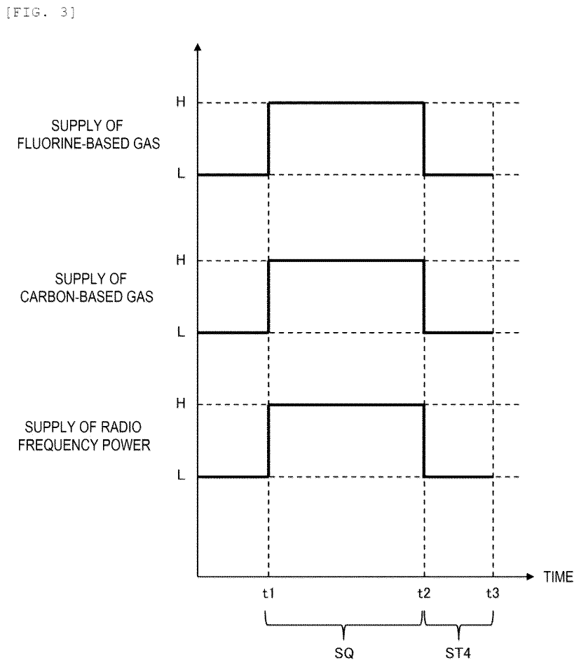

FIG. 3 shows a timing chart of the etching method. As described with reference to FIG. 2, the fluorine-based gas and the carbon-based gas are introduced into the processing container, the radio frequency power is simultaneously supplied to the plasma power supply, and the introduced gases are converted into the plasma to start the etching. Whether the predetermined etching is completed is detected by the well-known etching end point detection method. When it is determined that an end point is reached (when it is determined that the stop condition is satisfied), the inside of the processing container is evacuated, and the process is ended.

In the present embodiment, nitrogen trifluoride (NF₃) was used as the fluorine-based gas and supplied to the processing container at a flow rate of 10 ml/min by the flow rate controller group 130, and methane (CH₄) was used as the carbon-based gas and supplied to the processing container at a flow rate of 5 ml/min also by the flow rate controller group 130. Further, nitrogen (N₂) was similarly supplied to the processing container at a flow rate of 200 ml/min by the flow rate controller group 130. Thereafter, a microwave power supplied from the plasma power supply 107 was set to 600 W, and a temperature on a wafer surface was set to 40° C. to start the etching processing.

In addition to nitrogen trifluoride (NF₃), as the fluorine-based gas used as the etching gas, sulfur hexafluoride (SF₆), carbon tetrafluoride (CF₄), trifluoro methane (CHF₃), and fluoro methane (CH₃F) may be used. An etching rate differs depending on a type of the etching gas. Not only one type of gas, but also a mixed gas thereof may be used. As a carbon-based gas used for filling (deposition) pores (voids) and seams (joints) in an object to be processed with deposits (precipitates) while performing the etching with the fluorine-based gas, it is possible to use a gas species represented by a chemical formula C_{X}H_{Y} (X, Y are natural numbers) in addition to the methane gas described above.

With respect to an amount of deposition per unit time (speed), if the gas flow rate is the same, the larger the number of C, the larger the amount becomes. That is, the amount of deposition per unit time in the case of C₂H₆ (ethane gas) is larger than that of CH₄. During the deposition, radical species having a high adhesion coefficient referred to as C are deposited in large amounts on an upper portion of a hole. A radical species having an adhesion coefficient lower than C, such as CF₂, is deposited on a void portion in addition to the upper portion of the hole. On the other hand, when the amount of deposition is too large, the etching rate decreases. When the gas flow rate is large, a rate of the deposition increases, and an etch stop occurs. Accordingly, it is desirable to experimentally obtain an optimal set value according to the object to be processed by using the gas species and the gas flow rate of the fluorine-based gas as the etching gas, and the gas species and the gas flow rate of the carbon-based gas as a deposition gas as parameters.

In the present embodiment, parameters as shown in Table 1 were used.

TABLE 1
Table 1

| Fluorine-based gas | Carbon-based gas | Dilution gas |
|---|---|---|
| NF₃: 10 ml/min | CH₄: 5 ml/min | Ar: 200 ml/min |
| SF₆: 15 ml/min | C₂H₆: 5 ml/min | Ar: 200 ml/min |

According to experiments conducted by the present inventors, when a mixed gas of the fluorine-based gas and the carbon-based gas having a flow rate ratio such that an amount of substance of the carbon atoms with respect to an amount of substance of fluorine atoms contained in the fluorine-based gas was 0.1% or more and 30% or less was used, a balance between the etching rate and the deposition of the seam portion was good.

The ratio of the amount of substance of the carbon atoms contained in the carbon-based gas to the amount of substance of the fluorine atoms contained in the fluorine-based gas is preferably 10% or more and 20% or less. In this case, when the number of C in the carbon-based gas molecules is doubled, it is preferable to halve the flow rate of the carbon-based gas with respect to the flow rate of the fluorine-based gas.

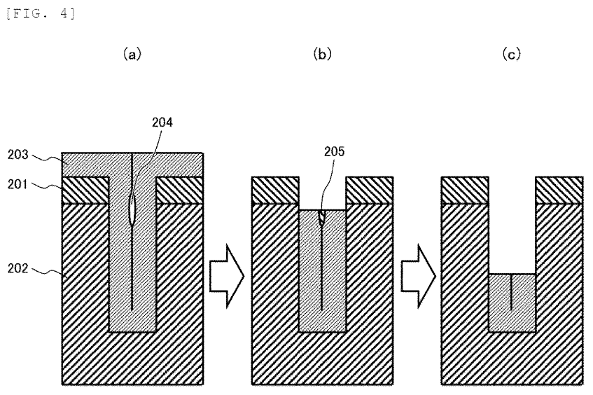

Next, a film structure of the wafer used in the present embodiment will be described with reference to (a) to (c) of FIG. 4. In the film structure of the wafer in (a) of FIG. 4, a silicon nitride (SiN) film 201 as a hard mask layer is used as a mask, and a silicon (Si) film 202 has a fin-shaped structure. A Low-k film, for example, a SiOC film 203 is formed around the silicon (Si) film 202. The SiOC film 203 has a seam 204 in the film. In order to flatly etch the SiOC film 203, it is necessary to process the SiOC film 203 while preventing a damage to the seam portion.

(b) of FIG. 4 is a diagram showing a concept of the etching method according to the present embodiment. By adding methane (CH₄) to a fluorine-based gas as the etching gas, a carbon-based component is mainly deposited on the void or the seam portion, and the void and the seam portion are prevented from being preferentially etched during the etching to prevent a defect. In addition to methane gas, a gas species represented by the chemical formula C_{X}H_{Y} (X and Y are natural numbers) may be used as a gas species to be deposited (deposition) on the pore or the seam portion.

Further, etching equivalent to that in the case where the seam is included can be performed for a structure not including the seam.

(c) of FIG. 4 is a view showing an etching shape when the wafer is processed by the etching method according to the present embodiment. The SiOC film 203 is etched, and a surface of the SiOC film 203 has a flat shape.

Even when plasma ions are emitted, a shape of the SiOC film 203 can be etched flatly by the plasma processing method according to the invention. However, since the silicon (Si) film 202 is etched, a method of emitting plasma radicals is more preferable. An example of a reason for etching the silicon (Si) film 202 by the plasma ions is an electron shading phenomenon. When the SiOC film 203 is etched, a sidewall of the silicon (Si) film 202 is charged by the ions. As the etching progresses, an aspect ratio of a trench hole increases and incident curvature of ions due to the charged sidewall increases, and the etching with respect to the silicon (Si) film 202 is likely to occur.

Although etch back in the vertical direction is shown in order to describe a shape, the etching with the radicals in a horizontal direction can also be performed.

Although an example of a fin field-effect transistor (FinFET) is described above in the present embodiment, the invention is also applicable to a gate all around (GAA) structure or a complementary field-effect transistor (CFET).

### REFERENCE SIGNS LIST

101 vacuum container
102 top plate
103 turbo molecular pump
104 dry pump
105 waveguide
106 matching device
107 plasma power supply
108 solenoid coil
109 shower plate
110 gas supply pipe
111 sample stage
112 ion shielding plate
113 bias matching device
114 biasing radio frequency power supply
115 control device
201 SiN film
202 Si film
203 SiOC film
204 seam in film

1. A plasma processing method for plasma etching a Low-k film having a void, comprising:
etching the Low-k film containing a silicon element using plasma generated by a mixed gas of a fluorine element containing gas and a carbon element containing gas.

2. The plasma processing method according to claim 1, wherein
the Low-k film is
a Low-k film embedded between a silicon channel and a silicon channel in a fin field-effect transistor (FinFET),
a Low-k film separating a transistor and a transistor in a gate all around (GAA) structure, or
a Low-k film separating a transistor and a transistor in a complementary field-effect transistor (CFET).

3. The plasma processing method according to claim 1, wherein
the Low-k film is etched using a radical generated by the plasma.

4. The plasma processing method according to claim 2, wherein
the Low-k film is etched using a radical generated by the plasma.

5. The plasma processing method according to claim 1, wherein
the fluorine element containing gas includes any one of a nitrogen trifluoride gas (NF₃), a sulfur hexafluoride gas (SF₆), a carbon tetrafluoride gas (CF₄), a trifluoro methane gas (CHF₃), and a fluoro methane gas (CH₃F).

6. The plasma processing method according to claim 1, wherein
the carbon element containing gas contains a C_{X}H_{Y} gas, and
the X and the Y are natural numbers.

7. The plasma processing method according to claim 6, wherein
the carbon element containing gas contains a methane gas (CH₄).

8. The plasma processing method according to claim 1, wherein
the mixed gas of the fluorine element containing gas and the carbon element containing gas is a mixed gas of a nitrogen trifluoride gas (NF₃) and a methane gas (CH₄).

9. The plasma processing method according to claim 8, wherein
the Low-k film is a SiOC film.

10. The plasma processing method according to claim 9, wherein
the SiOC film is subjected to etch back.

11. The plasma processing method according to claim 8, wherein
an argon gas (Ar) is added to the mixed gas of the nitrogen trifluoride gas (NF₃) and methane gas (CH₄).

12. The plasma processing method according to claim 11, wherein
a ratio of a gas flow rate of the methane gas (CH₄) to a gas flow rate of the nitrogen trifluoride gas (NF₃) is 0.1% or more and 30% or less.

13. The plasma processing method according to claim 1, wherein
a temperature of a sample stage configured to allow an object to be processed formed with the Low-k film to be placed is equal to or higher than a liquefaction temperature of a gas.
